(19) United States
(12) Patent Application Publication
(10) Pub. No.: US 2021/0289652 A1
(43) Pub. Date: Sep. 16, 2021

(54) DEVICE MOUNTS

(71) Applicant: Hewlett-Packard Development Company, L.P., Spring, TX (US)

(72) Inventors: Yao Wen Fan, Taipei (TW); Pei Yu Wang, Taipei (TW); Yu Wei Tan, Taipei (TW); Huang Chung Hung, Taipei (TW)

(21) Appl. No.: 16/481,843

(22) PCT Filed: Sep. 14, 2017
(86) PCT No.: PCT/US2017/051510

§ 371 Date: Jul. 30, 2019

(51) Int. Cl. H05K 7/14; F16B 5/02; H05K 1/02

(52) U.S. Cl. CPC H05K 7/1417; F16B 5/02; H05K 2201/10409; H05K 1/02; H05K 2201/2036; H05K 7/1427

(57) ABSTRACT

In an example, a device mount may include a plurality of mounting standoffs which may be arranged in a mounting arrangement. Each mounting standoff of the plurality of mounting standoffs may include a fixed end and a free end disposed away from the fixed end. The fixed end may securably mount to a chassis of an electronic device. Additionally, the free end may engage with a mounting interface of a device board. The mounting standoff may also include a threaded cavity extending into the mounting standoff from the fixed end. The mounting standoff may also include a retention nut to engage with the free end to fix the device board to the mounting standoff.

### BACKGROUND

Electronic devices may have a housing or enclosure within which components of the electronic device may be disposed. Such electronic devices, and thus enclosures thereof, may be continually reducing in size and footprint to make the electronic device more compact and/or desirable to an end user. In order to accommodate smaller and smaller form factors of electronic devices, components disposed within the enclosures of electronic devices may also be continually shrinking in size. Such components may include device boards and circuit boards, and thus it may be desirable to avoid wasted space and inefficient layout of components on such device boards and/or circuit boards.

### BRIEF DESCRIPTION OF THE DRAWINGS

FIG. 1A is a perspective view of an example device mount.

FIG. 1B is a perspective view of an example mounting standoff of an example device mount.

FIG. 2A is a perspective view of an example device board assembly having an example device mount.

FIG. 2B is a perspective cutaway view of an example device board assembly having an example device mount.

FIG. 2C is a cross-sectional view of an example device board assembly having an example device mount.

FIG. 3A is a front perspective view of an example electronic device having an example device mount.

FIG. 3B is a rear perspective view of an example electronic device having an example device mount.

FIG. 3C is a cross-sectional view of an example electronic device having an example device mount.

### DETAILED DESCRIPTION

Electronic devices may have a housing or enclosure within which components of the electronic device may be disposed. Such electronic devices, and thus enclosures thereof, may be continually reducing in size and footprint to make the electronic device more compact, lighter, cheaper, and/or more desirable to an end user. In order to accommodate smaller and smaller form factors of electronic devices, components disposed within their enclosures may also be continually shrinking in size. Such components may include device boards such as system boards or circuit boards, and thus it may be desirable to avoid wasted space and inefficient layout of components on such device boards.

Device boards may be mounted within enclosures of electronic devices by securably fastening the device board to the enclosure. Such secure installation may ensure the device board does not move around and is not accidentally damaged, and may also enable the secure mounting of other internal components near the device board. In some situations, a device board may be installed within an electronic device enclosure by mounting the device board directly to a wall or panel of the enclosure using mechanical fasteners such as screws, bolts, standoffs, and/or other fasteners. Such fasteners may attach directly to the device board, thus necessitating that portions of the device board be free of other components and/or electrical traces in order to accommodate the fasteners. Since it may be desirable to avoid wasted space on a device board to enable the electronic device to have a smaller overall size, it may also be desirably to minimize the number of such blank or empty portions of the device board.

In some situations, it may also be desirable to include an exterior mounting system or exterior mounting features on the enclosure of an electronic device in order to enable the electronic device to be mounted to another device, or to have another device be mounted to the electronic device. Such external mounting features or systems may include mechanical fasteners that extend from an external wall of the electronic device enclosure into the enclosure. In situations wherein a device board is mounted within the enclosure adjacent to such an external wall, such external mounting features may be accommodated by including blank portions or through holes or apertures on the device board to avoid interference of the device board with the external mounting features. Thus, in order to mount the device board to the enclosure, as well as include external mounting features on the electronic device, the device board may have an undesirably high amount of blank or unusable portions.

In some implementations, it may be desirable to minimize the number of blank or unusable portions on a device board, yet still be able to securely mount the device board within an enclosure and also include external mounting features on the electronic device. Implementations of the present disclosure provide device mounts which include mounting standoffs which may enable a device board to be securely mounted within an electronic device enclosure, and which may also act as external mounting features for the electronic device. Thus, implementations of the present disclosure may enable blank or unusable portions of a device board to be minimized, thereby enabling the device board to have a smaller size.

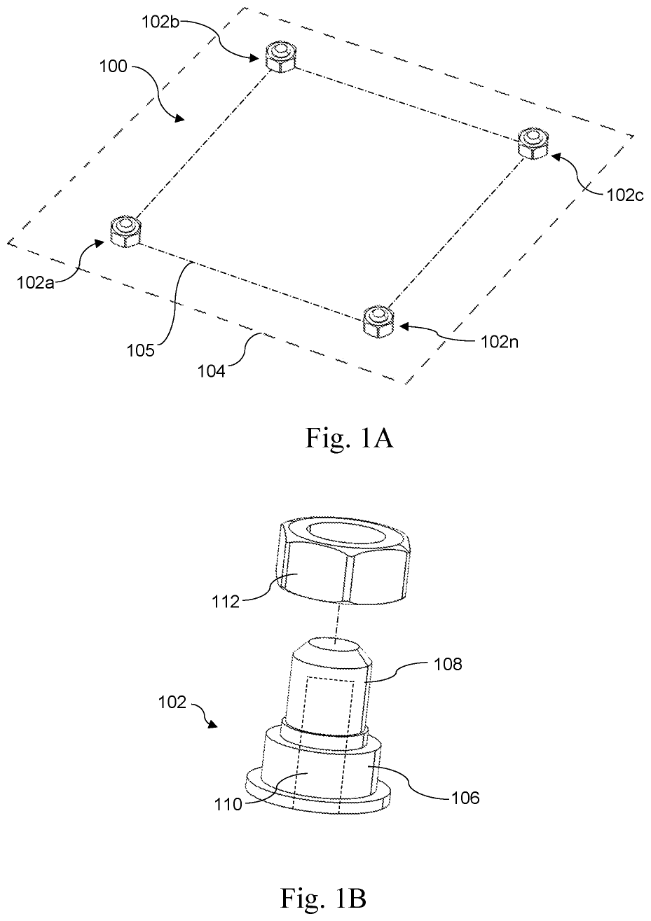

Referring now to FIG. 1A, a perspective view of an example device mount 100 is illustrated. Device mount 100 may include a plurality of mounting standoffs 102a, 102b, 102c . . . 102n, which may collectively be referred to as mounting standoffs 102, and which may be arranged in a mounting arrangement 105. Referring additionally to FIG. 1B, a perspective view of an example mounting standoff 102 (e.g., one of the plurality of mounting standoffs 102 of FIG. 1A) is illustrated. Each mounting standoff of the plurality of mounting standoffs 102 may include a fixed end 106 and a free end 108 disposed away from the fixed end 106. The fixed end 106 may securably mount to a chassis of an electronic device. Additionally, the free end 108 may engage with a mounting interface of a device board 104, illustrated in FIG. 1A for reference. Mounting standoff 102 may also include a threaded cavity extending into the mounting standoff 102 from the fixed end 106. The mounting standoff 102, in further implementations, may also include a retention nut 112 to engage with the free end 108 to fix the device board 104 to the mounting standoff 102.

In some implementations, the mounting standoff 102 may have a cylindrical or round structure, such that the fixed end 106 has a first diameter, and the free end 108 has a second diameter, smaller than the first diameter, as shown in FIG. 1B. In other implementations, the mounting standoff 102 may have a cuboid structure having rectangular faces and corners, or may have another structure with different geometry.

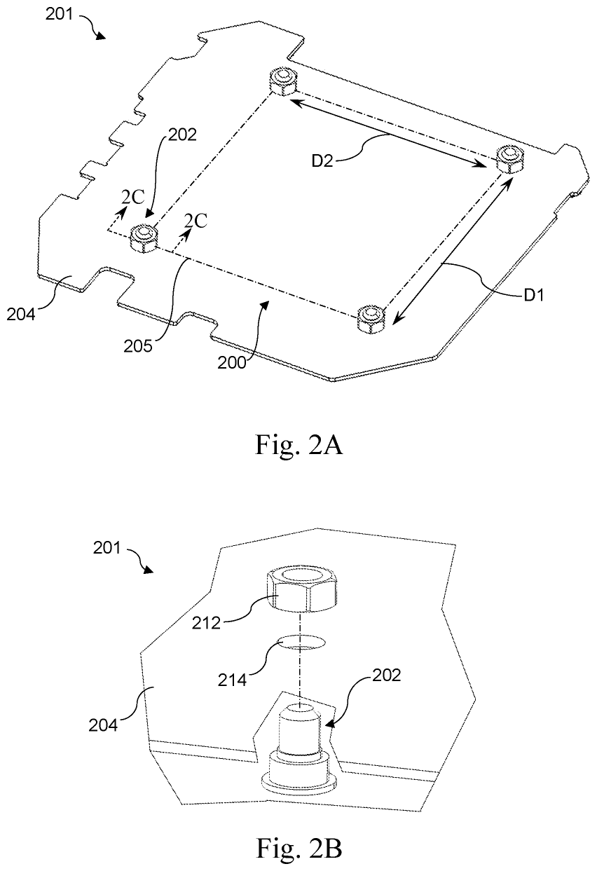

Referring now to FIG. 2A, a perspective view of an example device board assembly 201 of an electronic device is illustrated. Device board assembly 201 may include a device board 204 and a device mount 200 having a plurality of mounting standoffs 202. Example device mount 200 and mounting standoffs 202 may be similar to example device mount 100 and mounting standoffs 102, described above. Further, the similarly-named elements of example device mount 200 and mounting standoffs 202 may be similar in function and/or structure to the respective elements of example device mount 100 and mounting standoffs 102, as they are described above.

In some implementations, the device board 204 may structurally support and electrically connect multiple electronic components. The device board 204 may, in some implementations, electrically connect multiple electronic components with electrically conductive pathways. In further implementations, the device board 204 may be substantially made out of a non-conductive substrate with copper pathways formed onto the substrate. In some implementations, the non-conductive substrate may include silicon. The device board 204 may comprise a single-layer printed circuit board (PCB), or a multi-layer PCB in other implementations. In further implementations, the device board 204 may be a PCB assembly comprising computing components. In yet further examples, the device board 204 may be a system board or a motherboard for a computing device.

Referring additionally to FIG. 2B, a perspective cutaway view of the device board assembly 201 is illustrated, wherein one of the plurality of mounting standoffs 202 is illustrated in exploded form. The device board assembly 201, or the device board 204 thereof, may include a plurality of mounting interfaces 214 disposed on the device board 204. The mounting interfaces 214 may be disposed in a mounting arrangement 205 and may enable the device board assembly 201, or the device board 204, to be mounted within a chassis or enclosure of the electronic device. The mounting interfaces 214 may be apertures or openings in the device board 204, and, thus, may prevent other components or electrical pathways from being located on or near each mounting interface 214. Each mounting standoff 202 of the plurality of mounting standoffs 202 may engage with a separate mounting interface 214 of the plurality of mounting interfaces 214. In some implementations, each mounting interface 214 of the plurality of mounting interfaces 214 may be a separate aperture extending through the device board 204 and may be structured so as to engage with or receive a mounting standoff 202, or a free end thereof.

In some implementations, the mounting arrangement 205 may refer to a pattern or layout of the plurality of mounting interfaces 214 on the device board 204. Further, the mounting arrangement 205 may also refer to the associated pattern or layout of the plurality of mounting standoffs 202 if the mounting standoffs 202 are each engaged with one of the plurality of mounting interfaces 214. In some implementations, the mounting arrangement 205 may be a rectangular mounting arrangement, wherein the plurality of mounting interfaces 214, and thus the plurality of mounting standoffs 202, are arranged in a substantially rectangular pattern. In such an implementation, the mounting arrangement 205 may have a first distance D1 and a second distance D2 separating the mounting interfaces 214 from each other. Further, in some implementations, the plurality of mounting interfaces 214 may include four mounting interfaces 214 arranged at the corners of the rectangular mounting arrangement, i.e., in a 2x2 mounting pattern. Therefore, in such an implementation, the plurality of mounting standoffs 202 may include four mounting standoffs 202, each to engage with a separate mounting interface 214. In some implementations, the mounting arrangement 205 may be a square mounting arrangement, wherein the plurality of mounting interfaces 214 includes four mounting interfaces 214 arranged in a substantially square pattern, and D1 is substantially equal to D2. In yet further implementations, the mounting arrangement 205 may be a rectangular mounting arrangement wherein D2 is substantially equal to twice the length of Dl. In such an implementation, the plurality of mounting interfaces 214 may include six mounting interfaces 214, with one mounting interface 214 being located at each corner of the rectangular pattern, and an additional mounting interface 214 being located approximately halfway along D2 on both sides of the rectangular pattern, creating a 3x2 mounting pattern. In other implementations, the mounting arrangement 205 may be a pattern having a different shape or geometry, e.g., a pentagon or star geometry, a circular geometry, or a geometry of another shape.

In further implementations, the mounting arrangement 205 may be a commonly-used mounting arrangement for electronic devices. For example, the mounting arrangement 205 may be a Video Electronics Standards Association (VESA) Mounting Interface Standard (MIS). In such implementations, the mounting arrangement 205 may be a VESA MIS having a horizontal (e.g., D2) and vertical (e.g., D1) distance between the plurality of mounting interfaces 214, and thus the plurality of mounting standoffs 202, of approximately 100 millimeters (mm). In other implementations, the mounting arrangement 205 may be a VESA MIS having a horizontal and vertical distance between mounting interfaces 214, and thus mounting standoffs 202, of approximately 75 mm. In yet further implementations, the mounting arrangement 205 may be a VESA MIS of another size or layout, or may be a different type of mounting layout altogether.

Referring now to FIG. 2C, a cross-sectional view of example device board assembly 201 is illustrated, as taken along view line 2C-2C of FIG. 2A. FIG. 2C illustrates one of the plurality of mounting standoffs 202 as being fully engaged with and assembled to the device board 204 of the device board assembly 201. Example mounting standoff 202 may include a fixed end 206, and a free end 208, disposed away from the fixed end 206. The free end 208 may insertably engage with one of the plurality of mounting interfaces 214. The example mounting standoff 202 may also include a retention nut 212 to secure the one of the plurality of mounting interfaces 214 to the free end of the mounting standoff 202. Further, in some implementations, the fixed end 206 may have a rounded or cylindrical structure having a first diameter, and the free end 208 may have a rounded or cylindrical structure having a second diameter. The second diameter may be smaller than the first diameter such that the interface between the fixed end 206 and the free end 208 defines a shoulder 216. In further implementations, the first diameter, the second diameter, and the mounting interface 214 with which the example mounting standoff 202 is engaged may each be sized sufficiently such that the free end 208 is insertable into the mounting interface 214 while the fixed end 206 is not insertable into the mounting interface 214. In other words, the size of the mounting interface 214 may be larger than the second diameter, yet smaller than the first diameter. The shoulder 216 may be defined by the first diameter of the fixed end 206 and the second diameter of the free end 208 such that, upon full insertion of the free end 208 into the mounting interface 214, the shoulder 216 mates with, or abuts against the mounting interface 214, as illustrated in FIG. 2C. Further, the retention nut 212 may secure the respective mounting interface 214 to or against the shoulder 216 to fix or secure the device board 204 to the respective example mounting standoff 202.

The retention nut 212 may be a mechanical fastener having suitable structure to engage with the free end 208 of the respective mounting standoff 202. In some implementations, the free end 208, or a portion thereof, may have external threads, and the retention nut 212 may have complementary internal threads to engage with the external threads of the free end 208 such that the retention nut 212 may screw on to the free end 208 and secure the mounting interface 214 of the device board 204 to the mounting standoff 202. In other implementations, the retention nut 212 may engage with the free end 208 in a different manner, e.g., the retention nut 212 may slide axially on to the free end 208 and may be fixed in place on the free end 208 using friction, a clip, clasp, e-ring, spring pin, or with another mechanical interface suitable to hold the retention nut 212 against the mounting interface 214.

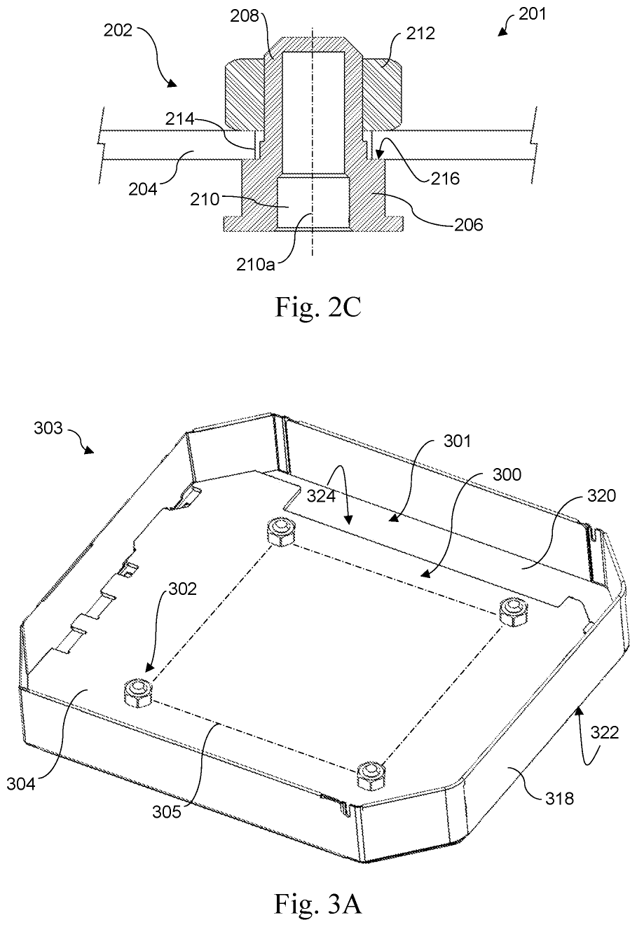

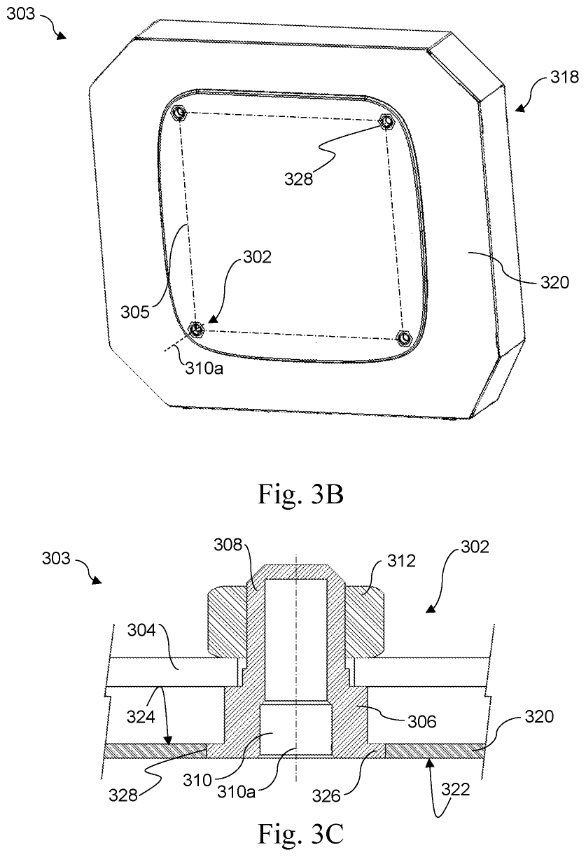

In some implementations, the example mounting standoff 202 may further include a threaded cavity 210 extending into the mounting standoff 202 from the fixed end 206. The threaded cavity 210 may be a cylindrical hole or cavity having a longitudinal axis 210a. The threaded cavity 210 is discussed in further detail below with regard to FIG. 3C.

Referring now to FIG. 3A, a front perspective view of an example electronic device 303 having an example device mount 300 is illustrated. In some implementations, the device mount 300 may be considered to be a part of a device board assembly 301, as described above, and in other implementations, may be considered as being a part of the electronic device 300. Example device mount 300 may be similar to example device mounts described above. Further, the similarly-named elements of example device mount 300 may be similar in function and/or structure to the respective elements of other example device mounts, as they are described above. Further, example device mount 300 may include a plurality of mounting standoffs 302.

In some implementations, the electronic device 303 may be a computing device. In further implementations, the electronic device 303 may be a desktop personal computer (PC), a small-form-factor, mini, or micro-computer, a tablet, a notebook computer or a portion thereof, or another type of computer. In other implementations, electronic device 303 may be an Internet modem or router, a cable or satellite set-top box, a device to provide smart-TV capabilities to a television, a portable hard drive, or another type of electronic device. Electronic device 303 may be any type of electronic device which may benefit from employing external mounting features such that other devices may be mounted to electronic device 303, or such that the electronic device 303 may be mounted on to another device. Such other devices may include displays, monitors, other computers or computer towers, a mounting rack or wall mount for an electronic device, or other devices.

Electronic device 303 may include a chassis 318. Chassis 318 may be a housing, enclosure, or case, or a panel or portion thereof, or may be part of a frame, stand, or another component of the electronic device 303 having an exterior wall 320, sometimes referred to as a mounting wall 320. Electronic device 303 may also include a device board 304 disposed within the chassis 318 and adjacent to an interior side 324 of the mounting wall 320. Device board 304 may be considered as being a part of a device board assembly 301, in some implementations. In further implementations, the device board 304 may include a plurality of mounting interfaces, which may be apertures extending through the device board 304. The plurality of mounting interfaces are illustrated as being operably engaged with the plurality of mounting standoffs 302, and, thus, are hidden in FIG. 3A.

Referring additionally to FIG. 3B, a rear perspective view of example electronic device 303 is illustrated. Specifically, FIG. 3B illustrates an exterior side 322 of the mounting wall 320. The chassis may include a plurality of device mount features 328 arranged in a mounting arrangement 305 on the exterior side 322 of the mounting wall 320. The mounting arrangement 305 may be a rectangular or square mounting arrangement, in some implementations, and may be similar to mounting arrangement 205, discussed above. The plurality of mounting interfaces of the device board 304 may also be arranged in a complementary or corresponding mounting arrangement, such that, when the device board 304 is disposed correctly within the chassis 318, the plurality of mounting interfaces are aligned with the plurality of device mount features 328. Thus, the plurality of mounting standoffs 302 may engage with both the plurality of mounting interfaces of the device board 304, as well as the plurality of device mount features 328 in order to fix or mount the device board 304 within the chassis 318. Further detail of how the plurality of mounting standoffs 302 mount the device board 304 to the chassis 318 is discussed below regarding FIG. 3C.

Referring now to FIG. 3C, a cross-sectional view of example electronic device 303 is illustrated, detailing an example mounting standoff 302 of the plurality of mounting standoffs 302. The example mounting standoff 302 may include a fixed end 306, a free end 308, and a retention nut 312, which, in some implementations, may be similar to like-named elements discussed above. The fixed end 306 may securably engage with one of the plurality of device mount features 328 disposed in the mounting wall 320 of the chassis 318 in order to secure the mounting standoff 302 to the chassis 318. Each of the plurality of device mount features 328 may be an aperture or opening in the mounting wall 320, sized and structured to suitably receive and secure the fixed end 306. In some implementations, the fixed end 306 may include a mounting flange 326 to assist in securing the mounting standoff 302 to the mounting wall 320. In further implementations, the fixed end 306 of the mounting standoff 302 may be press fit into one of the plurality of device mount features 328. In other implementations, the fixed end 306 may be attached to or engaged with the device mount feature 328 in another manner. The device board 304, or the mounting interface thereof, may be secured to the free end 308 of the mounting standoff 302 by the retention nut 312, similar to as described above. Thus, the plurality of mounting standoffs 302 may securably mount the device board 304, or the device board assembly 301 therein, to the chassis 318 of the electronic device 303. In some implementations, the device board 304 may be secured to the chassis 318 only by the mounting standoffs 302, and not by any additional mechanical fasteners. Further, the plurality of mounting standoffs 302 may be arranged in the mounting arrangement 305 shared with the plurality of mounting interfaces and the plurality of device mount features 328.

Each of the plurality of mounting standoffs 302 may include a threaded cavity 310 having a longitudinal axis 310a. The threaded cavity 310 may extend into the fixed end 306, and thus may be exposed to the exterior side 322 of the mounting wall 320, as illustrated in FIG. 3C. The threaded cavity may be a blind hole or opening, or may be a through-hole or opening in the mounting standoff 302, and may be able to receive mounting hardware to fix the mounting standoff 302 to another device to which the electronic device 303 may be mounted. In some implementations, the threaded cavity 310 may have internal threads to engage with external threads of a threaded fastener. In further implementations, the threaded cavity may be threaded to receive a M4, M6, or M8 metric threaded fastener. In other implementations, the threaded cavity may be threaded to receive another type of threaded fastener. In yet other implementations, it is contemplated that the threaded cavity 310 may not be threaded at all, and instead may receive a mechanical fastener in an axially sliding manner, and may fix to such a fastener through friction or another way. The threaded cavity 310 of each of the plurality of mounting standoffs 302 may be axially aligned with the respective device mount feature 328 with which the mounting standoff 302 is engaged. Thus, the threaded cavities 310, and the longitudinal axes 310a thereof, may collectively be exposed to the exterior side 322 of the mounting wall 320 and may be collectively arranged in the mounting arrangement 305, as is illustrated in FIG. 3B. Thus, the threaded cavities 310 may be able to receive, from the exterior of the chassis 318, threaded mounting hardware and/or fasteners that may also be arranged in a mounting arrangement or pattern that is complementary or matching to the mounting arrangement 305.

Therefore, by mounting the device board 304 and/or device board assembly 301 within the chassis 318 using the plurality of mounting standoffs 302 of the device mount 300, the device board 304 is secured within the electronic device 303, and the plurality of mounting standoffs 302 (or the threaded cavities 310 therein) can also be used as an external mounting system for the electronic device 303. Thus, instead of having a separate set of mounts or hardware for each of these tasks, each set of which would require dedicated blank space or apertures in the device board, a single set of mounting standoffs 302 may be employed, thereby minimizing the wasted space on the device board, and enabling the device board to be reduced in size.

What is claimed is:

1. A device mount, comprising:
a plurality of mounting standoffs arranged in a mounting arrangement, each mounting standoff comprising:
a fixed end having a first diameter to securably mount to a chassis of an electronic device;
a free end away from the fixed end and having a second diameter, smaller than the first diameter, to engage with a mounting interface of a device board;
a threaded cavity extending into the mounting standoff from the fixed end; and
a retention nut to engage with the free end to fix the device board to the mounting standoff.

2. The device mount of claim 1, wherein each mounting standoff includes a shoulder defined by the first diameter of the fixed end and the second diameter of the free end, wherein the retention nut is to secure the respective mounting interface to the shoulder to fix the device board to the mounting standoff

3. The device mount of claim 1, wherein the plurality of mounting standoffs arranged in a mounting arrangement comprises four mounting standoffs arranged in a rectangular pattern.

4. The device mount of claim 3, wherein the mounting arrangement is a Video Electronics Standards Association (VESA) Mounting Interface Standard (MIS).

5. The device mount of claim 4, wherein the VESA MIS has a horizontal and vertical distance between the plurality of mounting standoffs of approximately 100 millimeters (mm).

6. The device mount of claim 4, wherein the VESA MIS has a horizontal and vertical distance between the plurality of mounting standoffs of approximately 75 millimeters (mm).

7. A device board assembly of an electronic device, comprising:
a device board;
a plurality of mounting interfaces disposed on the device board in a square mounting arrangement to mount the device board within a chassis of the electronic device; and
a device mount having a plurality of mounting standoffs, each mounting standoff to engage with a separate mounting interface of the plurality of mounting interfaces and comprising:
a fixed end to securably engage with a device mount feature of the chassis;
a free end to insertably engage with one of the plurality of mounting interfaces;
a retention nut to secure the mounting interface to the free end of the mounting standoff; and
a threaded cavity extending into the mounting standoff from the fixed end, the threaded cavity exposed to an exterior of the chassis,
wherein the threaded cavity of each mounting standoff of the plurality of mounting standoffs are collectively arranged in the square mounting arrangement.

8. The device board of claim 7, wherein each of the mounting interfaces is a separate aperture extending through the device board.

9. The device board of claim 8, wherein each of the plurality of mounting standoffs includes a shoulder to mate with the respective mounting interface, the retention nut to secure the respective mounting interface against the shoulder.

10. The device board of claim 7, wherein the square mounting arrangement is a Video Electronics Standards Association (VESA) Mounting Interface Standard (MIS).

11. An electronic device, comprising:
a chassis having a plurality of device mount features arranged in a rectangular mounting arrangement on an exterior side of a mounting wall of the chassis;
a device board disposed within the chassis adjacent to an interior side of the mounting wall and comprising a plurality of mounting apertures extending through the device board; and
a device mount having a plurality of mounting standoffs, each mounting standoff comprising:
a fixed end to securably engage with one of the plurality of device mount features to secure the mounting standoff to the chassis;
a threaded cavity extending into the fixed end and axially aligned with the respective device mount feature of the plurality of device mount features;
a free end to insertably engage with one of the plurality of mounting apertures; and
a retention nut to secure the device board to the free end of the mounting standoff,
wherein the threaded cavity of each mounting standoff of the plurality of mounting standoffs are collectively exposed to the exterior side of the mounting wall and arranged in the rectangular mounting arrangement.

12. The electronic device of claim 11, wherein the rectangular mounting arrangement is a Video Electronics Standards Association (VESA) Mounting Interface Standard (MIS).

13. The electronic device of claim 12, wherein the device board is secured to the chassis only by the plurality of mounting standoffs.

14. The electronic device of claim 11, wherein the device board is a printed circuit board assembly comprising computing components.

15. The electronic device of claim 14, wherein the electronic device is small-form-factor computer.
